(19) United States
(12) Patent Application Publication
(10) Pub. No.: US 2023/0110268 A1
(43) Pub. Date: Apr. 13, 2023

(54) Coated High Permeability Metal Shield For Reducing Electronic Noise In Wearable Devices

(71) Applicant: Google LLC, Mountain View, CA (US)

(72) Inventors: Yao Ding, San Jose, CA (US); Nan Xu, Sunnyvale, CA (US)

(21) Appl. No.: 17/497,018

(22) Filed: Oct. 8, 2021

(51) Int. Cl. H04R 1/10; H01Q 1/52; H05K 9/00; H05K 7/14

(52) U.S. Cl. CPC H04R 1/1016; H01Q 1/526; H05K 7/1427; H05K 9/0084

(57) ABSTRACT

A high permeability metal (mu-metal) shield is placed in close proximity of a main logic board (MLB) of a wearable device, such as an earbud, to reduce eNoise. Radio frequency current flow induced by an antenna radiator will flow over the MLB and its associated ground plane, including the mu-metal shield. To reduce an impact of the mu-metal shield on antenna performance, a coating process is done on the mu-metal shield, by developing a thin layer of high conductivity, low permeability copper or silver on top of the mu-metal.

### BACKGROUND

Portable electronic devices include one or more antennas for transmitting and receiving signals in various communication bands. Antenna design for small electronic devices, such as wearable devices, can be very challenging because of the constrained form factors of such devices. For example, while a smart phone may have limited space for housing its antennas, earbuds with a compact form factor would necessarily have even less space. The limited space often impacts antenna performance, which may be measured by radiation efficiency and bandwidth. For example, antennas having a bigger volume typically have a higher efficiency. Moreover, a physical clearance between the antenna and other components is small, which causes high radio frequency (RF) coupling between the antenna and other components, such as an input touchpad. The high RF coupling leads to antenna performance degradation and large variations of the antenna’s performance due to the large tolerance of other components in assembly. Antenna performance for wearable devices may also be severely impacted by body effects due to the close proximity to the wearer, which may cause detuning, attenuation, and shadowing of the antenna.

Another issue that can arise with small form factor devices is that electrical noise (eNoise) may result from an arrangement of components and may degrade overall quality of the device. The typical ways to contain the magnetic field coupling is through the shielding. High permeability shielding is more effective to direct the magnetic flux generated by audio band low frequency noise. However, high permeability, high resistivity shielding can cause antenna performance degradation.

### BRIEF SUMMARY

The present disclosure provides a design for a wearable computing device, such as an earbud. To effectively suppress excessive magnetic field, a high permeability metal (mu-metal) shield is placed in close proximity of a main logic board (MLB). The shield may have a footprint similar to a shape of the MLB. The MLB and associated ground extension are effectively part of the antenna system.. Radio frequency surface current induced by an antenna radiator will flow over the MLB and associated ground plane, including the mu-metal shield. Any attenuation to the surface current due to resistivity of the mu-metal material will in turn degrade antenna radiated performance. To avoid having the high permeability high resistivity eNoise shield to attenuate the induced RF surface current, a coating process is done on the mu-metal shield, by developing a thin layer of high conductivity, low permeability copper or silver on top of the mu-metal.

One aspect of the disclosure provides an earbud, comprising a housing comprising an outer shell and an internal cavity, an antenna system within the housing, the antenna system comprising an antenna, ground, and a main logic board (MLB), a battery within the internal cavity of the housing, the battery supplying power to the MLB, a speaker within the housing, the speaker being in electrical communication with the MLB and the battery, and a coated high permeability metal shield positioned between the antenna system and the battery, the coated high permeability metal shield being coated with a high conductivity low loss material.

According to some examples, the high conductivity low loss material includes at least one of copper or silver. The high permeability metal shield may be, for example, between 20-2000 microns thick. The coating of the high permeability metal shield may have a thickness based on a frequency range of communication utilized by the antenna system. The antenna system may be configured for radio frequency (RF) communication. The thickness of the coating may be, for example, 2 microns. The coated high permeability metal shield may have a footprint corresponding to a shape of the MLB. In some examples, the housing of the earbud may include a bulb portion and an extension portion, wherein the extension portion is configured for insertion into a user’s ear canal and the bulb portion is configured for housing the antenna system. The high permeability metal shield may include a material having a permeability of 10k or more.

Another aspect of the disclosure provides a wearable electronic device, comprising a housing shaped to be worn on a human body, wherein at least one first surface of the housing is shaped to come in contact with the body and at least one second surface of the housing is shaped to be exposed when worn on the body, an antenna system positioned in proximity to the at least one second surface of the housing, the antenna system comprising an antenna, ground, and a main logic board (MLB), a battery within the housing, the battery supplying power to the MLB, a speaker within the housing, the speaker being in electrical communication with the MLB and the battery, and a coated high permeability metal shield positioned between the antenna system and the battery, the coated high permeability metal shield being coated with a high conductivity low loss material.

Yet another aspect of the disclosure provides an audio device, comprising a housing, an antenna, a main logic board (MLB) positioned within the housing an in electrical communication with the antenna, a battery within the housing, the battery supplying power to the MLB, a speaker within the housing, the speaker being in electrical communication with the MLB and the battery, and a coated high permeability metal shield positioned between the antenna system and the battery, the coated high permeability metal shield being coated with a high conductivity low loss material.

### BRIEF DESCRIPTION OF THE DRAWINGS

FIG. 1 is a cross-sectional view of an example earbud including an antenna according to aspects of the disclosure.

FIG. 2 is an enlarged cross-sectional view of an example coated mu-metal shield according to aspects of the disclosure.

FIG. 3 illustrates an example of skin depth according to aspects of the disclosure.

FIG. 4 is an example chart illustrating skin depth in copper according to aspects of the disclosure.

### DETAILED DESCRIPTION

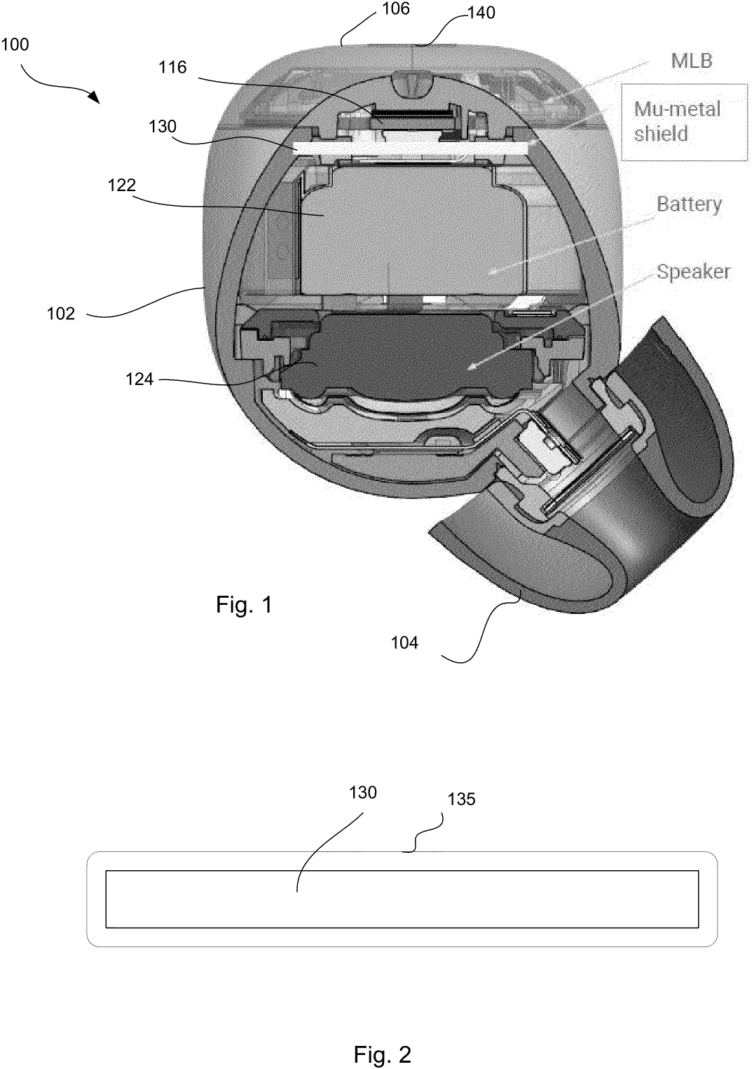

FIG. 1 illustrates a cross-section of an example wearable device, particularly an earbud 100. The earbud 100 includes a housing, which may include an outer shell and an internal cavity for housing a plurality of electronic components. In this example, the housing includes a bulb portion 102 and an extension portion 104. When worn by a user, extension portion 104 is inserted into the user’s ear canal, such that the bulb portion rests within a cavity of the user’s outer ear. In some examples, a top surface 106 of the housing does not extend beyond some parts of the outer ear, such as the pinna, earflap, or other portions. In other examples, the top surface 106 may extend beyond a plane including at least part of the user’s outer ear. While the housing is shown as having a bulb portion 102, an extension portion 104, and a relatively flat top surface 106, it should be understood that various modifications may be made to a size and shape of the housing.

Inside the housing is a number of components that operate to receive signals from associated devices and emit sounds corresponding to the signals into the user’s ear. For example, the earbud 100 may receive short range wireless audio signals from a mobile phone, music player, gaming device, or other electronic computing device. The earbud 100 may buffer the received signals and convert them into sound waves emitted through a speaker. Such reception, buffering, conversion, and emitting of signals requires a significant number of electronic components, though only some are described in detail herein. For example, battery 122 may supply power to various components, while speaker 124 emits sound. In some examples, the earbud 100 may further include a microphone or other device for capturing voice input from a user.

An upper portion of the earbud 100 includes an antenna 140 and a main logic board (MLB) 116. According to some examples, the upper portion may include a mu-metal shield 130

The earbud may include other features, such as a touchpad for receiving active user input. For example, a user may tap the touchpad to pause or play music, to switch the earbud 100 from a sound emitting mode to a voice input mode, to activate a pairing of the earbud 100 with other devices, or to perform any of a number of other functions. In some examples, touching or tapping the touchpad on different portions, for different durations of time, in different sequences, or in other distinct ways can be used to distinguish between a variety of desired user inputs. The touchpad may be positioned at an exposed surface of the earbud 100 for ease and convenience of access by a user’s finger to enter input. For example, the touchpad may be inside or outside of the housing.

The MLB 116 may include a microprocessor or other hardware for performing operations. By way of example only, such operations may include detecting user input, identifying a function corresponding to the user input, and executing the function. In some examples, the MLB 116 may include a Bluetooth chip. It may include a radio frequency (RF) signal source coupled to an antenna feed.

An antenna 140 may be positioned near a surface of the earbud that is exposed with respect to the user’s ear when the earbud 100 is worn. For example, while sides of the bulb portion 102 may be in contact with portions of the user’s ear when inserted, top surface 106 may be exposed to open air. This improves reception by the antenna with less interference from body parts or earbud components. The antenna may be inside or outside of the housing. According to some examples, the antenna 140 may be a flexible printed circuit (FPC) antenna taped to an inner surface of the housing.

According to some examples, the MLB 116 and associated ground extension may be part of an antenna system. RF current flow induced by a radiator of the antenna will flow over the MLB 116 and associated ground plane. A high permeability metal (mu-metal) shield 130 is placed between the MLB 116 and the battery 122 and speaker 124 to prevent the RF current from reaching the battery 122 and speaker 124. High permeability may refer to any metal having a permeability of approximately 10k or more. The mu-metal shield 130 reduces eNoise caused by magnetic coupling.

The mu-metal shield 130 may be placed in close proximity to the MLB 116. The shield 130 may have a similar footprint to that of the MLB 116 shape.

As seen in FIG. 2, the mu-metal shield 130 is coated with a high conductivity low loss material, such as coating 135. Examples of such material for the coating 135 include copper, silver, etc. The high conductivity low loss material coated on the outer layer of the mu-metal shield 130 reduces loss without impacting the shielding effect of the mu-metal.

The shield 130 may be, for example, between approximately 20-2000 microns thick. A thickness of the coating 135 may be based on a calculated skin depth. A skin effect is a tendency of alternative electric current (AC) to become distributed within a conductor such that the current density is largest near the surface of the conductor and decreases exponentially with greater depths in the conductor.

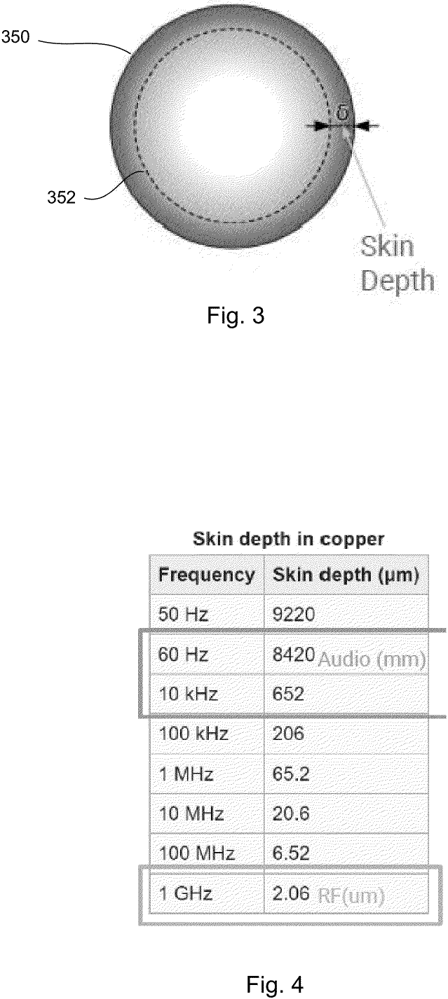

FIG. 3 illustrates a cross-section of a conductor 350. The conductor 350 will carry electrical current, but an extent to which the electrical current is evenly distributed across the cross-section is defined by skin depth 352. In the example shown, the skin depth 352 is illustrated by a dashed line at a radial depth δ with respect to an outer perimeter of the conductor.

While current for low frequency signals may flow through the entire cross-section of the conductor, current for higher-frequency signals may only traverse a shallow layer close to the outer perimeter of the conductor 350. FIG. 4 illustrates an example chart of various frequency levels and corresponding skin depth for a given material, such as copper. As seen from the table, if an antenna is excited at a low frequency, such as 50 Hz, skin depth is high. Conversely, at high frequency, such as 1 GHz, skin depth is low.

Accordingly, referring back to FIG. 2, a thickness of the coating 135 may be determined based on the frequency for communications with an antenna of the wearable device. For example, for an RF frequency band, the coating 135 may only be approximately 2 microns thick.

The antennas described above provide for efficient operation of devices, particularly for small factor wearable electronic devices. Each antenna is small enough and thin enough to fit inside an earbud, and is compatible with other components, such as a touchpad, PCB, etc. The antennas are arranged in the earbuds in a way to maximize a separation distance between the antenna and the user’s ear, thereby reducing the body effect and specific absorption rate, while allowing for a relatively large antenna volume. The antenna arrangement also largely avoids interference from a user’s finger touching the earbud to provide input.

Unless otherwise stated, the foregoing alternative examples are not mutually exclusive, but may be implemented in various combinations to achieve unique advantages. As these and other variations and combinations of the features discussed above can be utilized without departing from the subject matter defined by the claims, the foregoing description of the embodiments should be taken by way of illustration rather than by way of limitation of the subject matter defined by the claims. In addition, the provision of the examples described herein, as well as clauses phrased as “such as,” “including” and the like, should not be interpreted as limiting the subject matter of the claims to the specific examples; rather, the examples are intended to illustrate only one of many possible embodiments. Further, the same reference numbers in different drawings can identify the same or similar elements.

1. An earbud, comprising:
a housing comprising an outer shell and an internal cavity;
an antenna system within the housing, the antenna system comprising an antenna, ground, and a main logic board (MLB);
a battery within the internal cavity of the housing, the battery supplying power to the MLB;
a speaker within the housing, the speaker being in electrical communication with the MLB and the battery; and
a coated high permeability metal shield positioned between the antenna system and the battery, the coated high permeability metal shield being coated with a high conductivity low loss material.

2. The earbud of claim 1, wherein the high conductivity low loss material comprises at least one of copper or silver.

3. The earbud of claim 1, wherein the high permeability metal shield is between 20-2000 microns thick.

4. The earbud of claim 1, wherein a coating of the high permeability metal shield has a thickness based on a frequency range of communication utilized by the antenna system.

5. The earbud of claim 4, wherein the antenna system is configured for radio frequency (RF) communication.

6. The earbud of claim 5, wherein the thickness of the coating is 2 microns.

7. The earbud of claim 1, wherein the coated high permeability metal shield has a footprint corresponding to a shape of the MLB.

8. The earbud of claim 1, wherein the housing comprises a bulb portion and an extension portion, wherein the extension portion is configured for insertion into a user’s ear canal and the bulb portion is configured for housing the antenna system.

9. The earbud of claim 1, wherein the high permeability metal shield comprises a material having a permeability of 10k or more.

10. A wearable electronic device, comprising:
a housing shaped to be worn on a human body, wherein at least one first surface of the housing is shaped to come in contact with the body and at least one second surface of the housing is shaped to be exposed when worn on the body;
an antenna system positioned in proximity to the at least one second surface of the housing, the antenna system comprising an antenna, ground, and a main logic board (MLB);
a battery within the housing, the battery supplying power to the MLB;
a speaker within the housing, the speaker being in electrical communication with the MLB and the battery; and
a coated high permeability metal shield positioned between the antenna system and the battery, the coated high permeability metal shield being coated with a high conductivity low loss material.

11. The wearable electronic device of claim 10, wherein the high conductivity low loss material comprises at least one of copper or silver.

12. The wearable electronic device of claim 10, wherein the high permeability metal shield is between 20-2000 microns thick.

13. The wearable electronic device of claim 10, wherein a coating of the high permeability metal shield has a thickness based on a frequency range of communication utilized by the antenna system.

14. The wearable electronic device of claim 13, wherein the antenna system is configured for radio frequency (RF) communication.

15. The wearable electronic device of claim 14, wherein the thickness of the coating is 2 microns.

16. The wearable electronic device of claim 10, wherein the coated high permeability metal shield has a footprint corresponding to a shape of the MLB.

17. The wearable electronic device of claim 10, wherein the high permeability metal shield comprises a material having a permeability of 10k or more.

18. The wearable electronic device of claim 10, wherein the wearable electronic device comprises an earbud.

19. The wearable electronic device of claim 18, wherein the housing comprises a bulb portion and an extension portion, wherein the extension portion is configured for insertion into a user’s ear canal.

20. An audio device, comprising:
a housing;
an antenna;
a main logic board (MLB) positioned within the housing an in electrical communication with the antenna;
a battery within the housing, the battery supplying power to the MLB;
a speaker within the housing, the speaker being in electrical communication with the MLB and the battery; and
a coated high permeability metal shield positioned between the antenna system and the battery, the coated high permeability metal shield being coated with a high conductivity low loss material.
